(19) United States
(12) Patent Application Publication
(10) Pub. No.: US 2007/0160756 A1
(43) Pub. Date: Jul. 12, 2007

(54) Apparatus and method for the deposition of ruthenium containing films

(76) Inventor: Helmuth Treichel, Milpitas, CA (US)

Correspondence Address: DORSEY & WHITNEY LLP, 555 CALIFORNIA STREET, SUITE 1000, SUITE 1000, SAN FRANCISCO, CA, 94104, US

(21) Appl. No.: 11/326,707

(22) Filed: Jan. 7, 2006

(51) Int. Cl. C23C 16/00

(52) U.S. Cl. 427/248.1

(57) ABSTRACT

The present invention provides a method for depositing a ruthenium metal compound containing film on one or more substrates. The desired metal compound is first dissolved in a suitable solvent. The precursor mixture is then vaporized and delivered to a process chamber to be used in the deposition of the metal compound on the substrates by process methods comprising CVD, MOCVD, ALD, and the like. This method results in the deposition of high quality, substantially uniform films. Additionally, the method makes efficient use of the metal compound component and reduces the cost for the deposition of the metal compound.

### FIELD OF THE INVENTION

The present invention relates generally to methods for depositing materials containing a metal atom in the formation of semiconductor devices. More specifically, the present invention relates to a method for the deposition of ruthenium based films.

### BACKGROUND OF THE INVENTION

Advanced specifications for semiconductor devices require that the critical dimensions of such devices continue to shrink. These critical dimensions comprise the line widths and spacing of structures as well as the thickness of critical layers such as the diffusion barrier layers used in the interconnect scheme, the gate dielectric layer used in the active area of the transistor, and the thickness of the electrode materials used to form capacitor structures. In addition to the physical constraints placed on these films, new materials must also be developed and characterized to meet increasingly demanding performance specifications.

Currently accepted practices for the deposition of many materials used in the manufacture of the semiconductor device are by physical vapor deposition (PVD), chemical vapor deposition (CVD), metal organic chemical vapor deposition (MOCVD), atomic layer deposition (ALD), and the like. These techniques are well known in the manufacturing of semiconductor devices. The physical mechanism of PVD yields poor step coverage (defined as the ratio of film thickness at the bottom or side wall of a via divided by the film thickness on a flat surface at the top of the via). The mechanism of CVD and MOCVD also yields deposited films with poor step coverage on high aspect ratio structures. Therefore, alternative methods are being explored for the deposition of layers for devices using 65 nm technology and below. The ALD technique is well suited to the deposition of a wide variety of both conductive and dielectric films used in the manufacture of a semiconductor device. The ALD technique has the advantage of depositing films with excellent step coverage as well as being a process that is used at lower temperatures than CVD or MOCVD. This is a desirable property of the technique.

The transistor structure in advanced semiconductor devices currently uses a silicon-oxygen-nitrogen (SiON) material as the gate dielectric and “doped” polysilicon as the gate electrode material. When the device technology reaches the 45 nm node and beyond, it is projected that the gate dielectric material will change to a “high-k” dielectric material such as hafnium-silicon-oxygen-nitrogen (HfSiON). Semiconductor devices are currently comprised on complimentary sets of n-type and p-type devices. Well known techniques such as ion implantation are used to tune the electrical behavior of the various types of transistors. With the implementation of new high-k dielectric materials, it would be desirable to develop and implement an electrode material that could be used on both the n-type and p-type transistors without requiring additional processing steps.

The capacitor structure in memory devices has generally used a “silicon-insulator-silicon” (SIS) multilayer structure to form the capacitor. In this structure, a thin film of “doped” polysilicon is used as the electrode. The polysilicon is generally doped with various species such as boron, phosphorous, arsenic, and the like to lower the electrical resistance of the polysilicon layer. This is well known in the art. The capacitor dielectric material has traditionally been silicon dioxide or silicon nitride. The stringent requirements of advanced memory devices are leading to the replacement of these dielectric materials with metal oxides that have a high-k.

Memory device roadmaps are showing a trend away from the traditional SIS capacitor to more advanced device architectures. To enhance the performance of the device, a lower resistivity material such as a metal or conductive metal oxide is replacing the polysilicon electrode material. If only one of the electrodes is changed, the device architecture is known as a “metal-insulator-silicon” (MIS) structure. If both electrodes are changed, then the device architecture is known as a “metal-insulator-metal” (MIM) structure.

The metals or conductive metal oxides chosen to replace the polysilicon electrodes in both applications must meet a number of requirements. They are chemically stable with respect to interaction with the surrounding materials over the temperatures encountered during the remainder of the device processing sequence. Some of the metals that might be considered for use as a capacitor electrode are not stable when placed in contact with the oxygen-containing dielectric material. The metal will then become oxidized at the interface and the resistivity of the electrode will rise to an unacceptable level. Thus, more developments are needed.

For advanced semiconductor device fabrication, liquid chemical precursors are generally preferred over solid chemical precursors for accurate chemical vapor delivery to the process chamber. Solid chemical precursors suffer from inconsistent surface area changes throughout the time of delivery. Additional criteria for chemical precursors used in these alternative techniques include high vapor pressure, low toxicity, good thermal stability, long shelf life, high purity, and low cost.

More recently, ruthenium and/or ruthenium oxide has found interest as a possible metal electrode for next-generation high-k gate technology, or as a possible metal electrode in next-generation dynamic random access member (DRAM) technology. Early development work has focused on ruthenium precursor compounds where the central metal atom is surrounded by substituted cyclopentadiene ligands. These precursors suffer from issues such as poor metal compound efficiency, high cost, and incorporation of carbon into the deposited film.

It is clear that the development of a method for depositing a metal electrode layer that minimizes the resistance of the electrode, maintains the stability of the various interfaces, and reduces the amount of carbon contamination while maintaining the beneficial properties and performance specifications would be desirable.

### BRIEF SUMMARY OF THE INVENTION

A number of new materials have been identified as candidates for use as the electrode material in advanced capacitor electrode and advanced gate electrode applications. Examples of materials comprise the noble metals of Group 8A (e.g. Ru, Rh, and Ir), their conductive oxides (e.g. RuO₄), and the like, with ruthenium and ruthenium oxides being particularly suitable.

In some embodiments, a method is provided that addresses these issues by dissolving the desired metal compound in a suitable solvent. The precursor mixture is then vaporized and conveyed to a process chamber wherein a plurality of substrates is held at a predetermined condition of temperature and pressure. Equal amounts of the precursor mixture are introduced to each substrate by the use of a distributed injector. Additionally, in some embodiments, the process chamber is equipped with a “cross-flow” liner apparatus that cooperates with the distributed injector to cause the precursor mixture to substantially uniformly flow across the surface of each substrate in a “cross-flow” like manner. The precursor mixture reacts with each heated substrate to eliminate the solvent and deposit a film comprising the desired metal compound. In this way, the efficiency of the use of the metal compound is increased, the cost of the film forming method is decreased, and the incorporation of carbon in the deposited film is reduced.

In another aspect of the invention, methods of forming a ruthenium containing film on the surface of one or more substrates housed in a chamber are provided, characterized in that: a gaseous ruthenium precursor mixture comprised of one or more ruthenium containing compounds and a solvent, and one or more reactive gases, are conveyed, either concurrently or sequentially, to the one or more substrates in a manner such that said precursor mixture and said reactive gases are conveyed across the surface of each of the one or more substrates.

In a further aspect of the inventions, methods of depositing a ruthenium containing film on the surface of one or more substrates housed in a chamber are provided, comprising the steps of: injecting a gaseous ruthenium precursor mixture comprised of one or more ruthenium containing compounds and a solvent into the chamber though a first distributed injector located at an injection peripheral edge of the substrate; and injecting one or more reactive gases into the chamber through a second distributed injector located at the injection peripheral edge of the substrate. The ruthenium precursor mixture and the reactive gases flow across the surface of each of the substrates in a parallel manner and are removed through one or more orifices located substantially opposite the injection peripheral edge of the substrate.

### BRIEF DESCRIPTION OF THE DRAWINGS

These and various other features and advantages of the present invention will be apparent upon reading of the following detailed description in conjunction with the accompanying drawings and the appended claims provided below, wherein:

FIG. 1 is a partial cross sectional view of one example of a deposition system utilizing “cross-flow” apparatus which may be employed to carry out embodiments of the present invention.

FIG. 2 is a top view of a semiconductor wafer illustrating a “cross-flow” gas flow pattern across the wafer according to one embodiment of the present invention.

FIG. 3 is a flow chart illustrating an exemplary method according to one embodiment of the present invention;

FIG. 4 is a flow chart depicting an exemplary method according to a different embodiment of the present invention.

FIG. 5 is a graph illustrating the atomic concentration % of a film deposited according to embodiments of the present invention; and

FIG. 6 is a graph showing Ruthenium film thickness on silicon dioxide as a function of deposition duration deposited according to embodiments of the present invention.

### DETAILED DESCRIPTION OF THE INVENTION

In some embodiment methods for the deposition of a metal compound containing material at low temperatures using process methods comprising chemical vapor deposition (CVD), metal organic chemical vapor deposition (MOCVD), atomic layer deposition (ALD), and the like are provided. In one embodiment of the present invention, a plurality of substrates is placed in a process chamber and is heated to the desired temperature. It is desirable that the temperature of the substrates during processing be equal to or below 550° C., preferably below 400° C., and most preferably below 300° C. Examples of suitable substrates include, but are not limited to, silicon wafers, gallium arsenide wafers, glass substrates as used in the manufacture of flat panel displays, “thin film head” substrates as used to manufacture memory disk drives for computers, substrates used in the manufacture of photonic devices, substrates used in the manufacture of micro-electro-mechanical systems (MEMS) devices, polymeric substrates as might be used for organic-based devices, and the like.

The desired metal compound precursor is dissolved in a suitable solvent. It has been found that the Group VIII metals (Fe, Co, Ni, Ru, Rh, Pd, Os, Ir, Pt) are well suited for use in the present invention, in particular ruthenium (Ru) has been found to be well suited. Generally, the metal compound precursor mixture is then vaporized and conveyed to the process chamber wherein the plurality of substrates is held at a predetermined condition of temperature and pressure. In some embodiments, the metal compound precursor mixture is delivered to the substrates in a cross-flow like manner where substantially equal amounts of the precursor mixture are introduced to each substrate by the use of one or more injectors. Substantially equal amounts of one or more reactive gases (such as oxygen containing compounds, and the like) are also delivered to each of the substrates in a cross-flow like by the use of the same or independent injector(s). Typically, the flow of metal compound precursors and reactive gases are separated. The metal compound precursor mixture reacts with the reactive gas and each heated substrate to eliminate the solvent and deposit a film on the substrate comprising the desired metal compound.

In some embodiments, the present invention is broadly described as methods of forming a ruthenium containing film on the surface of one or more substrates housed in a chamber, characterized in that: a gaseous ruthenium precursor mixture comprised of one or more ruthenium containing compounds and a solvent, and one or more reactive gases, are conveyed, either concurrently or sequentially, to the one or more substrates in a manner such that said precursor mixture and said reactive gases are conveyed across the surface of each of the one or more substrates.

In other embodiments, methods of depositing a ruthenium containing film on the surface of one or more substrates housed in a chamber are provided, comprising the steps of: injecting a gaseous ruthenium precursor mixture comprised of one or more ruthenium containing compounds and a solvent into the chamber though a first distributed injector located at an injection peripheral edge of the substrate. One or more reactive gases are injected into the chamber through a second distributed injector located at the injection peripheral edge of the substrate. The ruthenium precursor mixture and the reactive gases flow across the surface of each of the substrates in a parallel manner and are removed through one or more orifices located substantially opposite the injection peripheral edge of the substrate.

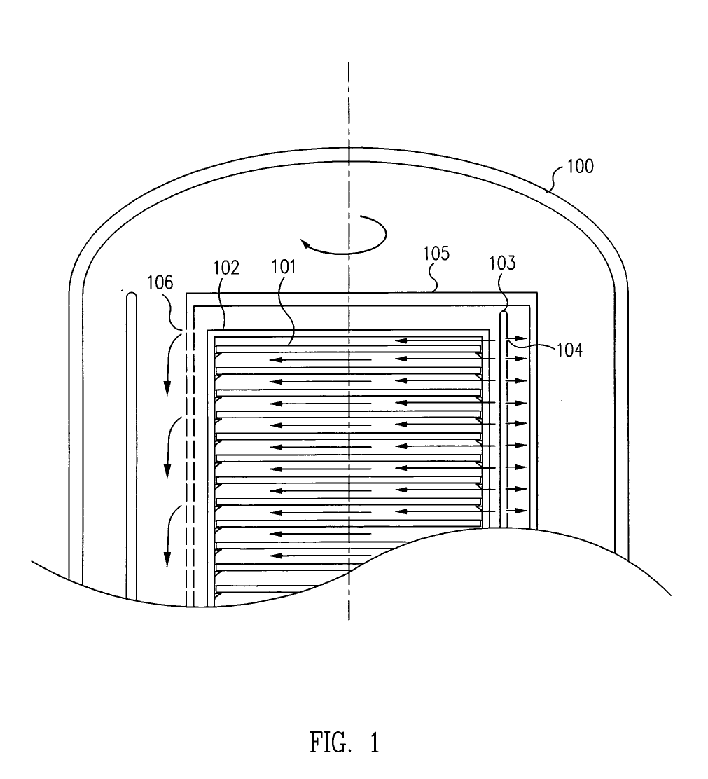

FIG. 1 illustrates a system which may be employed with embodiments of the method of the present invention. In this embodiment, the system is a “cross-flow” batch apparatus. A detailed description of this apparatus may be found in U.S. patent application Ser. Nos. 10/521,619 and 10/947,426, the disclosures of which are hereby incorporated by reference in their entirety. In FIG. 1, the process apparatus is illustrated as a vertical batch furnace for the processing of semiconductor substrates. Process chamber 100 forms an enclosed envelope capable of practicing reduced pressure process methods well known in the semiconductor manufacturing art. A heater assembly (not shown) is provided external to process chamber 100 and serves to heat the process chamber and substrates to the desired temperature. A plurality of substrates 101 are supported in boat or carrier 102. The plurality of substrates typically numbers between 1 and 200 product substrates and may contain additional test and dummy substrates.

Precursor, reactive, purging, and cleaning gases may be introduced into process chamber 100 through one or more injector tubes 103. Injector tube(s) 103 contain injector orifices 104 that are distributed substantially equally along the length of the injector tube(s) such that the total gas flow introduced into each injector tube(s), divided substantially equally along the length of each injector tube(s). This type of arrangement is also referred to as a distributed injector. Typically, injector orifices 104 are located at one peripheral edge of the substrate, referred to as the injection peripheral edge of the substrate. The injector orifices may be of any shape comprising holes, slots, slits, and the like. The design the injector tube diameter, number of injector orifices, and size of the injector orifices is selected by routine experimentation such that the gas flow exiting each injector orifice is substantially equal given the expected ranges of the gas supply pressure and gas supply flow rate.

In the exemplary embodiment the process chamber is equipped with a “cross-flow” liner 105 that cooperates with the distributed injector tube 103 to cause the precursor mixture to flow across the surface of each substrate in a “cross-flow” manner or parallel to the surface of the substrate. Cross-flow liner 105 is generally of cylindrical shape and is inserted into process chamber 100 and serves to divide the process chamber into two regions. Region one is the input gas region and lies on the inside of liner 105. Injector tube(s) 103 lie within region one. Region two is the exhaust gas region and lies on the outside of liner 105. Region one communicates with region two through liner or exhaust orifices 106 that are distributed substantially equally along the length of the liner 105, and are generally located substantially opposite the injection peripheral edge of the substrate. The liner orifices may be of any shape comprising holes, slots, slits, and the like. The pressure in region two is generally lower than the pressure in region one.

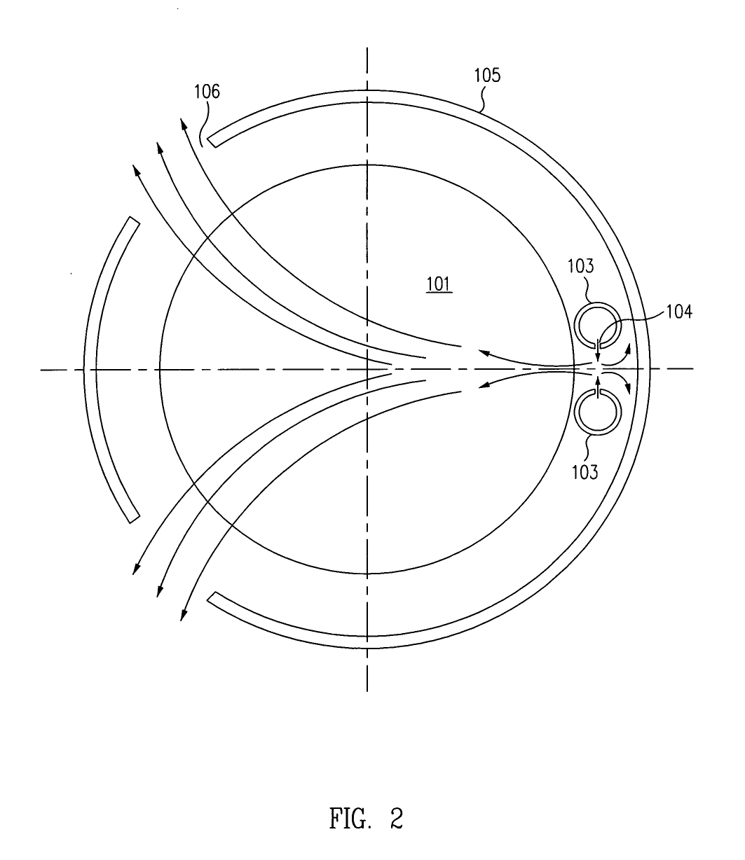

Injector tube(s) 103 and liner 105 cooperate in such a manner that the gas that exits the injector orifices 104 flows in a substantially uniform manner across the surface of the substrates and reacts to practice the desired process method. Unreacted gases and reaction byproduct gases exit region one through liner exhaust orifices 106 located opposite or substantially opposite the injector orifices 104 into region two and are removed from the process chamber by a suitable vacuum system (not shown). An illustration of the cross-flow gas pattern is shown in FIG. 2. As illustrated, gas flows across the surface of each the substrates in a manner substantially parallel to the surface of the substrate.

In conventional vertical furnace technology, the liner is formed from a solid cylinder, does not have liner orifices 106 and is open at the top. The precursor and reactive gases are introduced into the interior of the liner and exit through the top of the liner cylinder. This configuration leads to issues of poor film uniformity, gas depletion effects, incorporation of unwanted byproducts, and the like. Additionally, it has been found that this configuration requires higher deposition temperatures than the present invention.

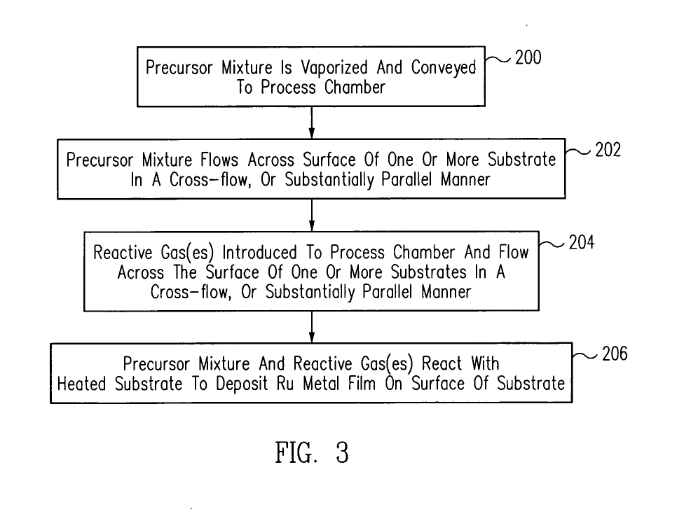

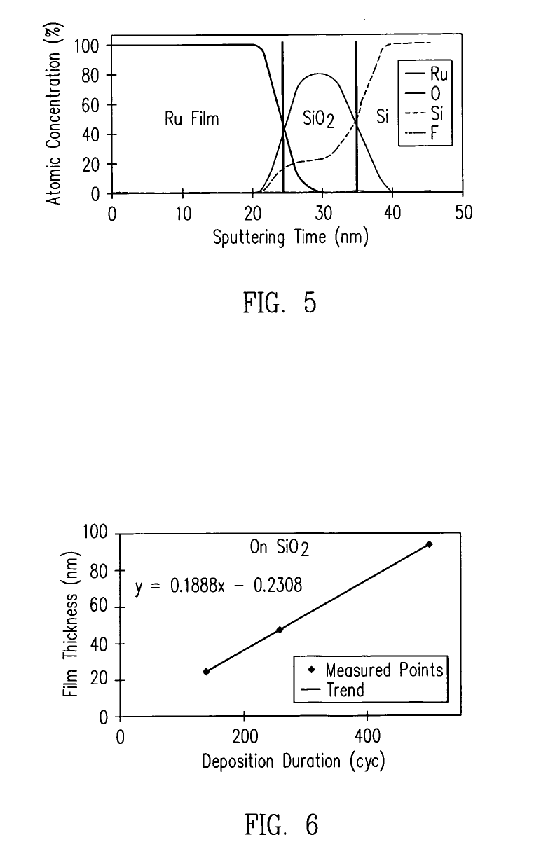

In one example of the present invention, it is desired to deposit a film of conductive ruthenium (Ru) on a semiconductor substrate to serve as an electrode material by a CVD method as illustrated in FIG. 3. A metal compound precursor mixture is prepared by dissolving up to 2 wt. % RuO₄ in a suitable solvent such as a member of the perfluoro class of solvents, more usually up to 0.2 wt % of RuO₄ is dissolved in the solvent. Any suitable solvent may be employed and it is preferred the solvent have a vapor pressure similar to the metal compound precursor over the operating temperature range. The precursor mixture is vaporized using any number of known techniques such as in a vaporizer, bubbler and the like and conveyed to the process chamber in step 200. In the exemplary embodiment the precursor mixture gas is introduced through a distributed injector and flows across the surface of the substrates in a cross-flow, or substantially parallel type manner at step 202. A reactive gas, in this example a reducing gas such as a forming gas is introduced into the process chamber through a second distributed injector, also in a cross-flow, or parallel like manner over the surface of the substrates at step 204. In some embodiments the forming gas is comprised of hydrogen in nitrogen or nitrogen, for example without limitation 5.5% hydrogen in nitrogen or nitrogen. The precursor mixture gas and the reducing gas react with the heated substrate surface to deposit a pure Ru metal film on the surface of the substrates at step 206. Advantageously, the Ru metal film exhibits low concentrations of oxygen impurities, as demonstrated by Auger analysis and shown in FIG. 5. Unreacted gases and reaction byproducts are swept out of the chamber through the plurality of liner orifices described previously. It has been discovered by the inventors that distributed injection of the metal compound precursors and reactive gases promotes improved uniformity of the deposition and reduces the incorporation of contaminants.

In some embodiments the method is carried out at process conditions comprising a substrate temperature in the range of between 50° C. and 550° C., a pressure in the range of between 1 mTorr and 50 Torr, and gas flow rates in the range of between 1 sccm and 20,000 sccm. More specifically, process conditions comprise a substrate temperature in the range of between 50° C. and 250° C., pressure in the range of between 50 mTorr and 3 Torr, and gas flow rates in the range of between 100 sccm and 3000 sccm. The results of an exemplary experimental deposition process conditions are shown in Table 1. In all of the data shown herein, the flow rate of RuO₄ may include a carrier gas, such as nitrogen.

TABLE 1

| | | | | | Forming |
|---|---|---|---|---|---|
| Experiment | | Tempera- | | RuO₄ Flow | Gas Flow |
| CVD-Ru | Dep rate | ture | Pressure | Rate | Rate |
| Test-CVD | 6 A/min | 200° C. | 2 Torr | 200 sccm | 1000 sccm |

In another example of the present invention, a film of a metal-nitrogen material such as RuₓN_{y} is deposited on a semiconductor substrate by a CVD method. A metal compound precursor mixture is prepared by dissolving up to 2 wt. % RuO₄ in a suitable solvent such as a member of the perfluoro class of solvents, more usually up to 0.2 wt % of RuO4 is dissolved in the solvent. The precursor mixture is vaporized using any number of known techniques and conveyed to the process chamber. In the exemplary embodiment the precursor mixture gas is introduced through a distributed injector. A reducing gas such as forming gas is mixed with a nitrogen containing gas such as NH₃, and the like, and is introduced into the process chamber through a second distributed injector. The precursor mixture gas and the reducing/nitriding gas react with the heated substrate surface to deposit a RuₓN_{y} film on the surface of the substrates. The method of the present invention promotes the deposition of a RuxNy film with low concentrations of oxygen impurities. Unreacted gases and reaction byproducts are swept out of the chamber through the plurality of liner orifices described previously.

In some embodiments the method of the present invention is carried out with the following process conditions: substrate temperature in the range of between 50° C. and 550° C., pressure in the range of between 1 mTorr and 50 Torr, and gas flow rates in the range of between 1 sccm and 20,000 sccm. More specifically, process conditions comprise substrate temperature in the range of between 50° C. and 250° C., pressure in the range of between 50 mTorr and 3 Torr, and gas flow rates in the range of between 100 sccm and 3000 sccm.

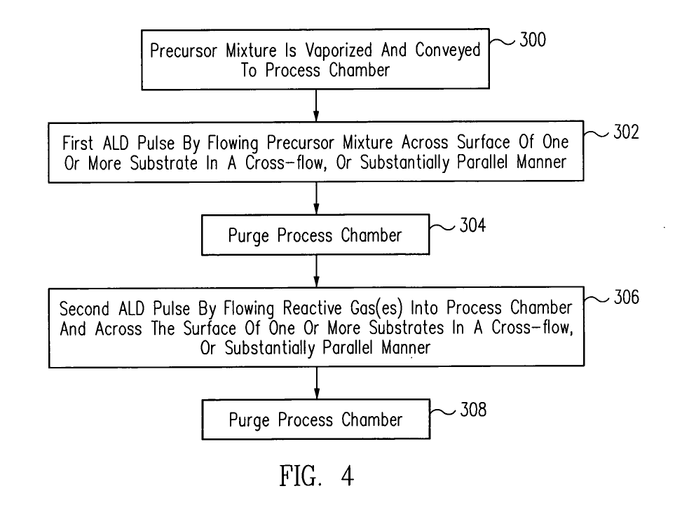

In another example of the present invention, it is desired to deposit a film of conductive Ru on a semiconductor substrate to serve as an electrode material by an ALD methods illustrated in FIG. 4 A metal compound precursor mixture is prepared by dissolving up to 2 wt. % RuO₄, more usually up to 0.2 wt % of RuO4, in a suitable solvent such as a member of the perfluoro class of solvents. The precursor mixture is vaporized using any number of known techniques and conveyed to the process chamber in step 300. The precursor mixture gas is introduced through a distributed injector as the first pulse of the ALD method in step 302. Unreacted and excess amounts of the precursor mixture gas are purged from the process chamber in step 304. A reactive gas in this case a reducing gas such as forming gas is introduced into the process chamber preferably, but not necessarily, through a second distributed injector to minimize gas phase reactions as the second pulse of the ALD method in step 306. Unreacted and excess amounts of the forming gas are purged from the process chamber in step 308. In the first pulse, the precursor mixture gas reacts with the heated substrate surface to substantially uniformly form a monolayer of RuO₄ on the substrate surface. In the second pulse the forming gas reacts with the RuO₄ monolayer to reduce the film to a pure Ru layer. This sequence is repeated until the desired thickness of Ru film on the substrate surface is achieved. Unreacted gases and reaction byproducts are swept out of the chamber through the plurality of liner orifices described previously. Again as stated above the cross flow, or distributed injection method of the invention improves the uniformity of the deposition and reduces the incorporation of contaminants. This effect is observed for both CVD and ALD techniques.

In the exemplary ALD process, the method of the present invention is carried out under the following process conditions: substrate temperature in the range of between 50° C. and 550° C., pressure in the range of between 1 mTorr and 50 Torr, and gas flow rates in each pulse in the range of between 1 sccm and 20,000 sccm, more typically between 10 sccm and 10,000 sccm More specifically, process conditions comprise substrate temperature in the range of between 50° C. and 250° C., pressure in the range of between 50 mTorr and 3 Torr during the pulse steps, and gas flow rates in the range of between 100 sccm and 3000 sccm. The results of an exemplary experimental deposition process conditions are shown in Table 2.

TABLE 2

| | | | | | Forming |
|---|---|---|---|---|---|
| Experiment | | Tempera- | | RuO₄ Flow | Gas Flow |
| ALD-Ru | Dep rate | ture | Pressure | Rate | Rate |
| Test-ALD | 1.2 | 200° C. | 2 Torr | 200 sccm | 1000 sccm |
| | A/cycle | | | | |

In another example of the present invention, it is desired to deposit a film of RuₓN_{y} on a semiconductor substrate by an ALD method. A metal compound precursor mixture is prepared by dissolving up to 2 wt. % RuO₄, more usually up to 0.2 wt % of RuO4, in a suitable solvent such as a member of the perfluoro class of solvents. The precursor mixture is vaporized using any number of known techniques and conveyed to the process chamber. The precursor mixture gas is introduced to the chamber as the first pulse of the ALD method. Preferably, the precursor mixture is introduced in a ‘cross-flow” manner, that is the flow of precursor mixture gas is substantially parallel to the surface of the substrate or wafer. In some embodiments the precursor gas mixture is introduced through the distributed injector configuration as described previously. Alternatively, different injectors or injection methods may be employed.

Unreacted and excess amounts of the precursor mixture gas are purged from the process chamber. Reactive gases, in this case a reducing gas such as a forming gas is mixed with a nitrogen containing gas such as NH₃ and the like, and are introduced into the process chamber through a second distributed injector as the second pulse of the ALD method. Preferably the reducing gas and the nitrogen containing gas are conveyed together through the second distributed injector. Unreacted and excess amounts of the reducing/nitriding gas are purged from the process chamber.

The precursor mixture gas reacts with the heated substrate surface to substantially uniformly form a monolayer of RuO₄ on the substrate surface in the first pulse. The reducing/nitriding gas reacts with the RuO₄ monolayer to reduce the film and form a RuₓN_{y} layer in the second pulse. This sequence is repeated until the desired thickness of RuₓN_{y} is achieved. Unreacted gases and reaction byproducts are swept out of the liner through the plurality of liner orifices described previously. This improves the uniformity of the deposit and reduces the incorporation of contaminants. In the exemplary embodiment the process conditions comprise: temperature in the range of between 50° C. and 550° C., pressure in the range of between 1 mTorr and 50 Torr, and gas flow rates in the range of between 1 sccm and 20,000 sccm, more typically between 10 sccm and 10,000 sccm. More specifically process conditions comprise: temperature in the range of between 50° C. and 250° C., pressure in the range of between 50 mTorr and 3 Torr, and gas flow rates in the range of between 100 sccm and 3000 sccm.

In another example of the present invention, a film of conductive RuO₂ is formed on a semiconductor substrate to serve as an electrode material by a CVD method. A metal compound precursor mixture is prepared by dissolving up to 2 wt. % RuO₄, more usually up to 0.2 wt % of RuO4, in a suitable solvent such as a member of the perfluoro class of solvents. The precursor mixture is vaporized using any number of known techniques and conveyed to the process chamber. The precursor mixture gas is introduced into the chamber Preferably, the precursor mixture is introduced in the ‘cross-flow” manner, where the flow of precursor mixture gas is substantially parallel to the surface of the substrate or wafer. In some embodiments the precursor gas mixture is introduced through the distributed injector configuration as described previously. A reducing gas such as a forming gas is introduced into the process chamber, in some embodiments through a second distributed injector to partially reduce the RuO₄ to RuO₂. Alternatively, different injectors or injection methods may be employed.

The precursor mixture gas and the reducing gas react with the heated substrate surface to substantially uniformly deposit a RuO₂ film with low concentrations of impurities. Unreacted gases and reaction byproducts are swept out of the liner through the plurality of liner orifices described previously. This improves the uniformity of the deposit and reduces the incorporation of contaminants.

In the exemplary embodiment, process conditions comprise: temperature in the range of between 50° C. and 550° C., pressure in the range of between 1 mTorr and 50 Torr, and gas flow rates in the range of between 1 sccm and 20,000 sccm, more typically between 10 sccm and 10,000 sccm. More specifically, process conditions comprise: temperature in the range of between 50° C. and 250° C., pressure range of between 50 mTorr and 3Torr, and gas flow rates of between 100 sccm and 3000 sccm. The results of an exemplary experimental deposition process conditions are shown in Table 3.

TABLE 3

| | | | | | Forming |
|---|---|---|---|---|---|
| Experiment | | Tempera- | | RuO₄ Flow | Gas Flow |
| CVD-RuO₂ | Dep rate | ture | Pressure | Rate | Rate |
| Test-CVD | 6 A/min | 200° C. | 2 Torr | 200 sccm | 1000 sccm |

In another example of the present invention, a film comprising RuOₓN_{y} is formed on a semiconductor substrate by CVD. The method of the invention comprises the following steps: A metal compound precursor mixture is prepared by dissolving up to 2 wt. % RuO₄ in a suitable solvent such as a member of the perfluoro class of solvents. The precursor mixture is vaporized using any number of known techniques and conveyed to the process chamber. The precursor mixture gas is introduced into the chamber. Preferably, the precursor mixture is introduced in the ‘cross-flow” manner, where the flow of precursor mixture gas is substantially parallel to the surface of the substrate or wafer. In some embodiments the precursor gas mixture is introduced through the distributed injector configuration as described previously. Reactive gases, in this example reducing gas such as a forming gas is mixed with a nitrogen containing gas such as NH₃ and the like, and is introduced into the process chamber through a second distributed injector to partially reduce the RuO₄ to RuO₂. Alternatively, different injectors or injection methods may be employed.

The precursor mixture gas and the reducing/nitriding gas react with the heated substrate surface to substantially uniformly deposit a RuOₓN_{y} film with low concentrations of impurities. Unreacted gases and reaction byproducts are swept out of the chamber through the plurality of liner orifices described previously. This improves the uniformity of the deposition and reduces the incorporation of contaminants in the resultant film. In the exemplary embodiment the method is carried out under process conditions comprising: substrate temperature in the range of between 50° C. and 550° C., pressure in the range of between 1 mTorr and 50 Torr, and gas flow rates in the range of between 1 sccm and 20,000 sccm, more typically between 10 sccm and 10,000 sccm. More specifically, the method is carried out under process conditions comprising substrate temperature in the range of between 50° C. and 250° C., pressure in the range of between 50 mTorr and 3 Torr, and gas flow rates in the range of between 100 sccm and 3000 sccm.

In another example of the present invention, a film of conductive RuO₂ is formed on a semiconductor substrate to serve as an electrode material by ALD. In the exemplary embodiment, methods are carried out in the following steps: A metal compound precursor mixture is prepared by dissolving up to 2 wt. % RuO₄, more usually up to 0.2 wt % of RuO4, in a suitable solvent such as a member of the perfluoro class of solvents. The precursor mixture is vaporized using any number of known techniques and conveyed to the process chamber. The precursor mixture gas is introduced into the chamber as the first pulse of the ALD method. Preferably, the precursor mixture gas is introduced in the ‘cross-flow” manner, where the flow of precursor mixture gas is substantially parallel to the surface of the substrate or wafer. In some embodiments the precursor mixture gas is introduced through the distributed injector configuration as described previously. Alternatively, different injectors or injection methods may be employed. Unreacted and excess amounts of the precursor mixture gas are purged from the process chamber. Reactive gases, in this example A reducing gas such as a forming gas is introduced into the process chamber through a second distributed injector as the second pulse of the ALD method. Unreacted and excess amounts of the forming gas are purged from the process chamber.

The precursor mixture gas reacts with the heated substrate surface to form a monolayer of RuO₄ on the substrate surface in the first pulse. The forming gas reacts with the RuO₄ monolayer to partially reduce the film to a RuO₂ layer in the second pulse. This sequence of pulses is repeated until the desired thickness of RuO₂ film is achieved. Unreacted gases and reaction byproducts are swept out of the chamber through the plurality of liner orifices described previously. This improves the uniformity of the deposit and reduces the incorporation of contaminants.

In the exemplary embodiment, the method is carried out under the following process conditions: substrate temperature in the range of between 50° C. and 550° C., pressure in the range of between 1 mTorr and 50 Torr, and gas flow rates in the range of between 1 sccm and 20,000 sccm, more typically between 10 sccm and 10,000 sccm. More specifically, exemplary process conditions comprise substrate temperature in the range of between 50° C. and 250° C., pressure in the range of between 50 mTorr and 3 Torr, and gas flow rates in the range of between 100 sccm and 3000 sccm. The results of exemplary experimental deposition process conditions are shown in Table 4.

TABLE 4

| | | | | | Forming |
|---|---|---|---|---|---|
| Experiment | | Tempera- | | RuO₄ Flow | Gas Flow |
| ALD-RuO₂ | Dep rate | ture | Pressure | Rate | Rate |
| Test-ALD | 1.2 | 200° C. | 2 Torr | 200 sccm | 1000 sccm |
| | A/cycle | | | | |

In another example of the present invention, a method is provided to deposit a film of RuOₓN_{y} on a semiconductor substrate by ALD. A metal compound precursor mixture is prepared by dissolving up to 2 wt. % RuO₄, more usually up to 0.2 wt % of RuO4, in a suitable solvent such as a member of the perfluoro class of solvents. The precursor mixture is vaporized using any number of known techniques and conveyed to the process chamber. The precursor mixture gas is introduced to one or more substrates, preferably but not necessarily through a distributed injector as the first pulse of the ALD method. Unreacted and excess amounts of the precursor mixture gas are purged from the process chamber. Reactive gases, in this example a reducing gas such as a forming gas is mixed with a nitrogen containing gas such as NH₃ and the like, and is introduced into the process chamber preferably through a second distributed injector as the second pulse of the ALD method. Preferably the reducing gas and the nitrogen containing gas are conveyed together through the second distributed injector. Unreacted and excess amounts of the reducing/nitriding gas are purged from the process chamber.

The precursor mixture gas reacts with the heated substrate surface to form a monolayer of RuO₄ on the substrate surface in the first pulse. The reducing/nitriding gas reacts with the RuO₄ monolayer to form a RuOₓN_{y} layer in the second pulse. This sequence of pulses is repeated until the desired thickness of RuOₓN_{y} is achieved. Unreacted gases and reaction byproducts are swept out of the liner through the plurality of liner orifices described previously. This improves the uniformity of the deposit and reduces the incorporation of contaminants.

In this embodiment the method is carried out under process conditions comprising substrate temperature in the range of between 50° C. and 550° C., pressure in the range of between 1 mTorr and 50 Torr, and gas flow rates in the range of between 1 sccm and 20,000 sccm, more usually between 10 sccm and 10,000 sccm. More specifically, the method is carried out under process conditions of: substrate temperature in the range of between 50° C. and 250° C., pressure in the range of between 50 mTorr and 3 Torr, and gas flow rates in the range of between 100 sccm and 3000 sccm.

### EXPERIMENTAL

A number of experiments were conducted. The experiments are described herein for illustration purposes only, and are not intended to limit the scope of the invention in any way. Experiments were conducted in an ALD system to form Ru films on the surface of substrates. In the experiments, RuO₄ at 0.12 wt % diluted in a solvent was used as the precursor. A reducing agent of H₂ at a vol % of 2 or less was used. The vapor pressure of RuO₄ was approximately 10 torr at 25° C., and approximately 24 torr at 40° C. The melting point is 24.4° C. and boiling point is 130° C. The solvent was selected to have a vapor pressure similar to RuO₄ over a wide temperature range.

ALD methods were run using the following illustrative process conditions: precursor pulse comprised of RuO4 at a flow rate of 0.014 sccm with 10 sccm N₂ carrier gas; pressure of 3 torr during the pulse step, and carried out at a temperature in the range of approximately 150 to 300° C. In some experiments an ALD cycle sequence was: RuO4 pulse for 2 seconds, followed by purge step for 6 seconds, followed by H₂ pulse for 1 second, followed by purge step for 6 seconds.

Ru films were deposited at a deposition rate of 2.2 A/cycle. FIG. 5 is a graph from Auger analysis showing the atomic composition of the Ru layer, silicon dioxide and silicon layers in a film stack. FIG. 6 illustrates the Ru film thickness deposited on silicon dioxide as a function of deposition duration. The films exhibited good adhesion, and no fluorine, carbon or oxygen impurities were present in the film under Auger analysis.

The foregoing description of specific embodiments of the invention has been presented for the purpose of illustration and description. They are not intended to be exhaustive or to limit the invention to the precise forms disclosed, and obviously many modifications, embodiments, and variations are possible in light of the above teaching. It is intended that the scope of the invention be defined by the claims appended hereto and their equivalents.

I claim:

1. A method of forming a ruthenium containing film on the surface of one or more substrates housed in a chamber, characterized in that: a gaseous ruthenium precursor mixture comprised of one or more ruthenium containing compounds and a solvent, and one or more reactive gases, are conveyed, either concurrently or sequentially, to the one or more substrates in a manner such that said precursor mixture and said reactive gases are conveyed across the surface of each of the one or more substrates.

2. The method of claim 1 where the ruthenium containing compound is RuO₄.

3. The method of claim 1 where the solvent is comprised of perfluoro solvents.

4. The method of claim 1 wherein the step of conveying the gaseous ruthenium precursor mixture and reactive gases further comprises:
injecting the ruthenium precursor mixture though a first distributed injector located at an injection peripheral edge of the substrate;
injecting the reactive gases through a second distributed injector located at the injection peripheral edge of the substrate;
where the ruthenium precursor mixture and the reactive gases flow across the surface of each of the substrates in a parallel manner and are removed through one or more orifices located substantially opposite the injection peripheral edge of the substrate.

5. The method of claim 1 wherein the method is carried out: at a substrate temperature in the range of 50° C. to 550° C., pressure in the range of 1 mTorr to 50 Torr, and at a total gas flow rate in the range of 1 sccm to 20,000 sccm.

6. The method of claim 1 wherein the ruthenium containing film formed is comprised of pure ruthenium metal.

7. The method of claim 1 wherein the ruthenium containing film formed is comprised of ruthenium oxide.

8. The method of claim 1 wherein the ruthenium containing film formed is comprised of ruthenium nitride.

9. The method of claim 1 wherein the ruthenium containing film formed is comprised of ruthenium oxynitride.

10. A method of depositing a ruthenium containing film on the surface of one or more substrates housed in a chamber, comprising:
injecting a gaseous ruthenium precursor mixture comprised of one or more ruthenium containing compounds and a solvent into the chamber though a first distributed injector located at an injection peripheral edge of the substrate; and
injecting one or more reactive gases into the chamber through a second distributed injector located at the injection peripheral edge of the substrate;
where the ruthenium precursor mixture and the reactive gases flow across the surface of each of the substrates in a parallel manner and are removed through one or more orifices located substantially opposite the injection peripheral edge of the substrate.

11. The method of claim 10 where the gaseous ruthenium precursor mixture and the reactive gases are injected into the chamber concurrently.

12. The method of claim 10 where the gaseous ruthenium precursor mixture and the reactive gases are injected into the chamber sequentially.

13. The method of claim 10 where the ruthenium containing compound is RuO₄.

14. The method of claim 10 where the solvent is comprised of perfluoro solvents

15. The method of claim 10 wherein the reactive gases comprises a reducing gas and a nitrogen containing gas which react with the gaseous ruthenium precursor mixture to form a film comprised of ruthenium oxynitride.

16. The method of claim 15 wherein ruthenium precursor mixture is injected into the chamber is a first ALD pulse, and the reducing gas and nitrogen containing gas are injected together in a second ALD pulse.

17. The method of claim 10 wherein the reactive gases comprises a nitrogen containing gas which react with the gaseous ruthenium precursor mixture to form a film comprised of ruthenium nitride.

18. The method of claim 10 wherein the reactive gases comprise one or more reducing gases which react with the gaseous ruthenium precursor mixture to form a pure ruthenium metal film.

19. The method of claim 10 wherein the gaseous ruthenium precursor mixture comprises a ruthenium oxygen compound and the reactive gases comprise one or more reducing gases, which react to form a film comprising ruthenium oxide material.
